(19) United States
(12) Patent Application Publication
(10) Pub. No.: US 2025/0205846 A1
(43) Pub. Date: Jun. 26, 2025

(54) POLISHING APPARATUS AND POLISHING METHOD

(71) Applicant: EBARA CORPORATION, Tokyo (JP)

(72) Inventors: Kohei OTA, Tokyo (JP); Nobuyuki TAKADA, Tokyo (JP)

(21) Appl. No.: 18/988,616

(22) Filed: Dec. 19, 2024

(30) Foreign Application Priority Data
Dec. 26, 2023 (JP) 2023-219085

(51) Int. Cl. B24B 37/005; B24B 37/04; B24B 37/10; H01L 21/306; H01L 21/66

(52) U.S. Cl. CPC B24B 37/005; B24B 37/042; B24B 37/10; H01L 21/30625; H01L 22/12

(57) ABSTRACT

A polishing apparatus that are simple in structure and capable of controlling a film thickness profile of a substrate with high accuracy is disclosed. The polishing apparatus includes a stage configured to hold the substrate and having a non-rotating structure, a plurality of pressing actuators, a pad holder, and a polishing-pad rotating mechanism.

### CROSS REFERENCE TO RELATED APPLICATION

This document claims priority to Japanese Patent Application No. 2023-219085 filed Dec. 26, 2023, the entire contents of which are hereby incorporated by reference.

### BACKGROUND

A precision required for each process in a manufacturing of recent semiconductor devices has already reached an order of several nm, and a chemical mechanical polishing (CMP) is no exception. In addition, with an increasing integration density of semiconductor integrated circuits, a miniaturization and multi-layering are accelerating.

Therefore, in order to realize such miniaturization and multi-layering, it is also necessary to limit a variation in film thickness after the CMP to the order of several nm over the entire surface of the wafer.

Japanese laid-open patent publication No. 2018-067609 discloses a face-up type polishing apparatus configured to locally polish a wafer and control a film thickness profile of the wafer. The polishing apparatus in Japanese laid-open patent publication No. 2018-067609 is configured to polish the wafer by pressing a polishing pad against the wafer while rotating a table that holds the wafer by a driving mechanism.

In order to precisely control the film thickness profile of the wafer, it is necessary to control the pressure of the polishing pad for each small area on the wafer; however, this requires the use of a polishing pad with a small diameter, which takes a long time to polish the wafer.

Japanese laid-open patent publication No. 2021-112797 discloses a face-up type polishing apparatus having a plurality of piezoelectric elements disposed inside a polishing head that holds the wafer. In this polishing apparatus, as in the polishing apparatus of Japanese laid-open patent publication No. 2018-067609, the wafer needs to be polished while the polishing head that holds the wafer is rotated.

In the configuration of Japanese laid-open patent publication No. 2021-112797, a plurality of power lines to which a plurality of piezoelectric elements are connected must be extended to the outside of the polishing head through a rotary connector, but connecting all of the power lines to a rotary connector would make the polishing apparatus complicated.

### SUMMARY

Therefore, there are provided a polishing apparatus and a polishing method that are simple in structure and capable of controlling the film thickness profile of a substrate with high accuracy.

Embodiments, which will be described below, relate to a polishing apparatus and a polishing method.

In an embodiment, there is provided a polishing apparatus comprising: a stage configured to hold a substrate with a surface to be polished facing upward, and having a non-rotating structure; a plurality of pressing actuators arranged inside the stage, and configured to independently press a specific portion of the substrate; a pad holder configured to hold a polishing pad and press the polishing pad against the surface to be polished; and a polishing-pad rotating mechanism configured to rotate the polishing pad about its own center.

In an embodiment, the polishing apparatus comprises a polishing-pad moving mechanism configured to move the polishing pad.

In an embodiment, the polishing-pad moving mechanism is configured to move the polishing pad along a spiral polishing trajectory on the surface to be polished.

In an embodiment, the polishing trajectory has: a first trajectory extending from a peripheral portion of the substrate toward a central portion of the substrate; and a second trajectory extending from the central portion of the substrate toward the peripheral portion of the substrate, and not overlapping with the first trajectory.

In an embodiment, the polishing apparatus includes a film thickness measuring device configured to detect a film thickness signal corresponding to a film thickness of the substrate.

In an embodiment, the polishing apparatus comprises a plurality of film thickness measuring devices, including the film thickness measuring device, arranged in a straight line, and the film thickness measuring devices are configured to detect a film thickness signal corresponding to the film thickness of the substrate along a linear measurement trajectory on the surface to be polished.

In an embodiment, the polishing apparatus comprises a polishing liquid supply device having a center supply nozzle configured to supply a polishing liquid from a center portion of the polishing pad.

In an embodiment, the polishing apparatus comprises a polishing liquid supply device having a peripheral supply nozzle arranged around the polishing pad, and the peripheral supply nozzle is configured to supply a polishing liquid to an upstream side of the polishing pad in a traveling direction of the polishing pad.

In an embodiment, the polishing apparatus comprises a suction device configured to vacuum-suck the substrate arranged on the stage, and the suction device comprises a vacuum line disposed inside the stage.

In an embodiment, at least one of the pressing actuators is an air cylinder having a hollow piston rod, and the vacuum line is connected to the piston rod.

In an embodiment, there is provided a polishing method comprising: holding a substrate with a surface to be polished of the substrate facing upward by a stage configured to house a plurality of pressing actuators; and polishing the substrate in a non-rotating state by pressing a polishing pad held by a pad holder against the surface to be polished while rotating the polishing pad around itself in a state in which a pressing pressure of a specific pressing actuator among a plurality of pressing actuators is made different from a pressing pressure of the other pressing actuators.

In an embodiment, moving the polishing pad along a spiral polishing trajectory on the surface to be polished when polishing the substrate.

In an embodiment, measuring a film thickness distribution of the substrate before polishing the substrate; and determining the pressing pressure by the pressing actuators based on the film thickness distribution.

In an embodiment, supplying a polishing liquid from a center supply nozzle disposed at a center portion of the polishing pad when polishing the substrate.

In an embodiment, supplying a polishing liquid from a peripheral supply nozzle disposed around the polishing pad to an upstream side of the polishing pad in a traveling direction of the polishing pad when polishing the substrate.

The polishing apparatus can polish the surface to be polished of the wafer by using the pressing actuators to form an uneven shape on the mounting surface of the stage according to a specific portion of the wafer. Since the stage has a non-rotating structure, the control line of the pressing actuator can be simplified. Therefore, the polishing apparatus can precisely control the film thickness profile of the substrate with a simple structure.

### BRIEF DESCRIPTION OF THE DRAWINGS

FIG. 1 is a perspective view showing one embodiment of a polishing apparatus;

FIG. 2 is a cross-sectional view showing the polishing apparatus shown in FIG. 1;

FIGS. 3A and 3B are views showing a polishing pad moving along an example of a polishing trajectory;

FIGS. 4A and 4B are views showing a polishing pad moving along another example of a polishing trajectory;

FIG. 5 is a view showing a plurality of pressing actuators arranged in a lattice pattern;

FIG. 6 is a view showing a stage on which the pressing actuators are arranged;

FIG. 7 is a view showing a film thickness measuring device that moves along a spiral measurement trajectory;

FIG. 8 is a view showing a plurality of film thickness measuring devices arranged in a line;

FIG. 9 is a view showing a film thickness measuring device attached to the polishing pad;

FIG. 10 is a view showing a center supply nozzle and a peripheral supply nozzle;

FIG. 11 is a view showing the center supply nozzle and the peripheral supply nozzle connected to the polishing pad arm;

FIG. 12A is a view showing a polishing liquid supply device having only the center supply nozzle, FIG. 12B is a view showing a polishing liquid supply device having only the peripheral supply nozzle, and FIG. 12C is a view showing the peripheral supply nozzle connected to a pad holder,

FIG. 13 is a view showing a polishing flow of a wafer by the polishing apparatus;

FIG. 14 is a perspective view showing another embodiment of the polishing apparatus; and

FIG. 15 is a view showing another embodiment of a suction device.

### DESCRIPTION OF EMBODIMENTS

Hereinafter, embodiments will be described with reference to the drawings. In the drawings described below, the same or corresponding components are denoted by the same reference numerals, and duplicated descriptions will be omitted. In the embodiments described below, a configuration of one embodiment that is not particularly described is the same as the other embodiments, so duplicated descriptions will be omitted.

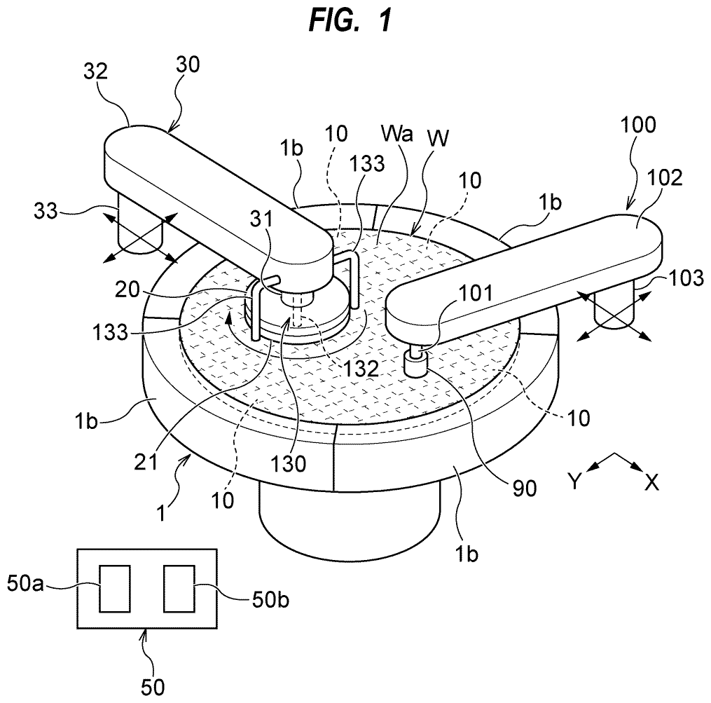

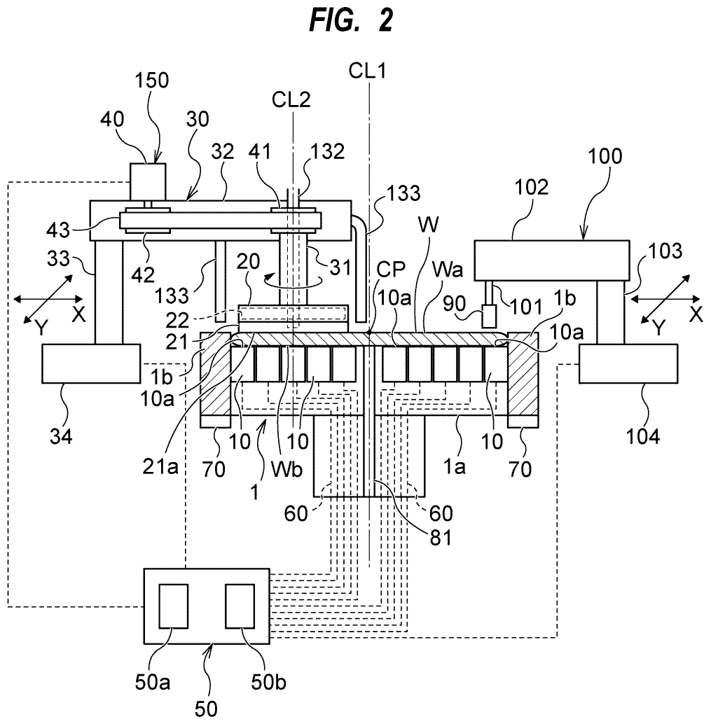

FIG. 1 is a perspective view showing one embodiment of a polishing apparatus. FIG. 2 is a cross-sectional view showing the polishing apparatus shown in FIG. 1. In the embodiment shown in FIGS. 1 and 2, the polishing apparatus is a polishing apparatus that polishes a wafer W (an example of a substrate) as an object to be polished with a surface to be polished Wa of the wafer W facing upward. Such a polishing apparatus is called a face-up type polishing apparatus.

The polishing apparatus includes a stage 1 having a non-rotating structure that holds the wafer W so that the surface to be polished Wa of the wafer W faces upward, a plurality of pressing actuators 10 that are arranged inside the stage 1 and independently press a specific portion of the wafer W, a pad holder 20 that holds a polishing pad 21 that is in sliding contact with the surface to be polished Wa, a film thickness measuring device 90 that detects a film thickness signal corresponding to the film thickness of the wafer W, and a control device 50 that controls operations of components of the polishing apparatus.

The stage 1 is configured to hold the wafer W, but is a non-rotating substrate holding device that does not rotate the held wafer W. More specifically, the non-rotating stage 1 is not connected to a rotation device such as a motor. When the stage 1 holds the wafer W, the central portion CP of the wafer W is located on a central axis line CL1 of the stage 1.

The polishing pad 21 is made of, for example, a polyurethane foam pad or sponge, and has a size (diameter) smaller than a size (diameter) of the wafer W. The polishing pad 21 has a polishing surface 21a that is pressed against the surface to be polished Wa. The polishing surface 21a faces downward and faces the surface to be polished Wa.

The pad holder 20 is configured to press the polishing pad 21 against the surface to be polished Wa. More specifically, the pad holder 20 has an air bag 22 (see FIG. 2) disposed therein, and the polishing pad 21 is disposed below the air bag 22.

Therefore, by supplying a compressed air from a compressed air source (not shown) to the air bag 22, the air bag 22 inflates and presses the polishing pad 21 down toward the surface to be polished Wa. The polishing pad 21 presses the polishing surface 21a against the surface to be polished Wa to polish the surface to be polished Wa.

The polishing apparatus includes a polishing pad moving mechanism 30 configured to move the polishing pad 21. The polishing pad moving mechanism 30 includes a rotary shaft 31 to which the pad holder 20 is connected, a polishing pad arm 32 to which the rotary shaft 31 is connected, a pivot shaft 33 to which the polishing pad arm 32 is connected, and a polishing-pad driving source 34 coupled to the pivot shaft 33.

The pad holder 20 is fixed to a lower end of the rotary shaft 31. As shown in FIG. 2, the rotary shaft 31 is coupled to a rotary motor 40 via pulleys 41 and 42 and a belt 43 stretched around the pulleys 41 and 42.

Therefore, the rotary motor 40, by its drive, rotates the rotary shaft 31 through the pulleys 41, 42 and the belt 43. The pad holder 20 fixed to the rotary shaft 31 and the polishing pad 21 held by the pad holder 20 rotate about a central axis line CL2 of the rotary shaft 31.

The rotary motor 40, the pulleys 41, 42, and the belt 43 constitute a polishing-pad rotating mechanism 150 that rotates the polishing pad 21 together with the pad holder 20 about the central axis line CL2.

The polishing-pad driving source 34 is configured to move the polishing pad arm 32 in an X-axis direction and a Y-axis direction via the pivot shaft 33. The X-axis direction and the Y-axis direction extend parallel to the surface to be polished Wa of the wafer W held on the stage 1 and are perpendicular to each other.

The polishing-pad driving source 34 moves the pad holder 20 and the polishing pad 21 in a direction parallel to the surface to be polished Wa (i.e., in the X-axis direction and the Y-axis direction) via the pivot shaft 33 and the polishing pad arm 32.

Although not shown, an example of the polishing-pad driving source 34 is a combination of an X-axis actuator (e.g., a combination of a ball screw extending in the X-axis direction and a servo motor) and a Y-axis actuator (e.g., a combination of a ball screw extending in the X-axis direction and a servo motor).

The control device 50 includes a storage device 50a in which a program is stored, and a calculation device 50b that executes calculations according to instructions included in the program. The storage device 50a includes a main storage device such as a RAM, and an auxiliary storage device such as a hard disk drive (HDD) or a solid state drive (SSD). Examples of the calculation device 50b include a CPU (Central Processing Unit) and a GPU (Graphics Processing Unit).

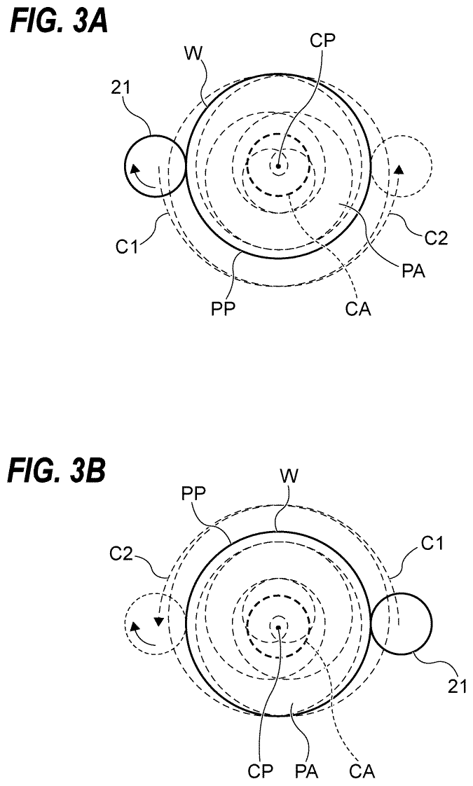

FIGS. 3A and 3B are views showing a polishing pad moving along an example of a polishing trajectory. In the embodiment shown in FIGS. 3A and 3B, the polishing pad 21 moves on the surface to be polished Wa along a spiral polishing trajectory (see dotted arrow) on the surface to be polished Wa to polish the surface to be polished Wa. The control device 50 is configured to operate the polishing-pad driving source 34 to move the polishing pad 21 along a predetermined polishing trajectory (e.g., the polishing trajectory according to the embodiment shown in FIGS. 3A and 3B) stored in the storage device 50a.

As shown in FIGS. 3A and 3B, the polishing trajectory has a first trajectory C1 extending from a peripheral portion PP of the wafer W toward a central portion CP of the wafer W, and a second trajectory C2 extending from the central portion CP of the wafer W toward the peripheral portion PP of the wafer W. Both the first trajectory C1 and the second trajectory C2 are polishing trajectories that do not pass over the central portion CP of the wafer W, but pass around the central portion CP.

The first trajectory C1 and the second trajectory C2 are formed so as not to overlap each other. Therefore, the polishing pad 21 is configured to uniformly polish the entire surface to be polished Wa by tracing different trajectories.

The polishing pad moving mechanism 30 is configured to continuously move the polishing pad 21 along a first trajectory C1 and a second trajectory C2. Therefore, the polishing pad 21 moves from the peripheral portion PP of the wafer W toward the central portion CP of the wafer W along the first trajectory C1 by an operation of the polishing-pad driving source 34, and then moves from the central portion CP of the wafer W toward the peripheral portion PP of the wafer W along the second trajectory C2.

In the embodiment shown in FIG. 3A, the polishing pad 21 moves along a spiral polishing trajectory (i.e., the first trajectory C1 and the second trajectory C2) that spirals around one direction (first rotation direction). In the embodiment shown in FIG. 3B, the polishing pad 21 moves along a spiral polishing trajectory (i.e., the first trajectory C1 and the second trajectory C2) that spirals around the same rotation direction as the first rotation direction.

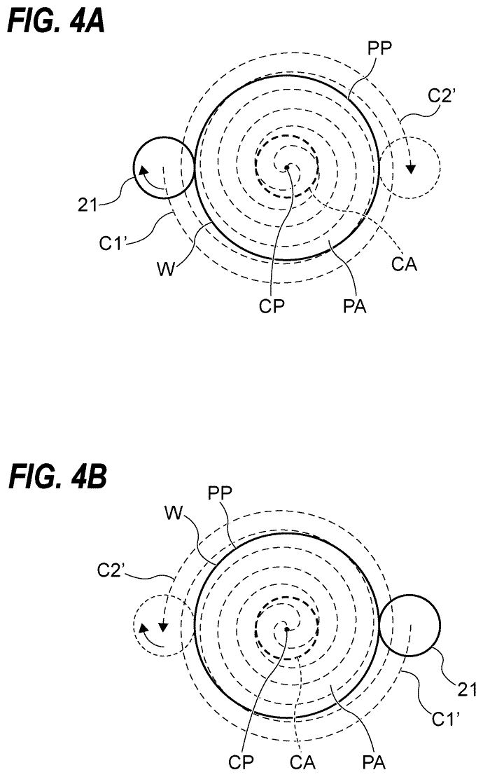

FIGS. 4A and 4B are views showing a polishing pad moving along another example of a polishing trajectory. In the embodiment shown in FIGS. 4A and 4B, the polishing pad 21 also oscillates on the surface to be polished Wa along a spiral polishing trajectory. The storage device 50a stores the polishing trajectory according to the embodiment shown in FIGS. 4A and 4B.

The polishing trajectory has a first trajectory C1′ extending from the peripheral portion PP of the wafer W toward the central portion CP of the wafer W, and a second trajectory C2′ extending from the central portion CP of the wafer W toward the peripheral portion PP of the wafer W. The first trajectory C1′ and the second trajectory C2′ are polishing trajectories that pass over the central portion CP of the wafer W.

In FIGS. 4A and 4B, the first trajectory C1′ and the second trajectory C2′ are formed so as not to overlap each other. Therefore, the polishing pad 21 is configured to uniformly polish the entire surface to be polished Wa by tracing different trajectories.

In the embodiment shown in FIG. 4A, the polishing pad 21 moves along a first spiral trajectory C1′ that spirals around the first rotational direction, and after reaching the central portion CP of the wafer W, moves along a second spiral trajectory C2′ that spirals around a second rotational direction opposite to the first rotational direction.

In the embodiment shown in FIG. 4B, the polishing pad 21 moves along the first spiral trajectory C1′ that spirals around a second rotation direction, and after reaching the central portion CP of the wafer W, moves along the second spiral trajectory C2′ that spirals around the first rotation direction.

As described above, the polishing pad 21 has a specific size. Therefore, the polishing pads 21 passing over the wafer W may not overlap uniformly. In other words, if a moving speed of the polishing pad 21 is constant, a time that the polishing pad 21 stays at a specific point (any one point) on the wafer W while the polishing pad 21 moves once from the peripheral portion PP of the wafer W to the central portion CP of the wafer W and from the central portion CP to the peripheral portion PP is not necessarily uniform on the wafer W.

Therefore, the control device 50 may control an amount of polishing of the wafer W by changing the moving speed of the polishing pad 21 moving along the polishing trajectory based on polishing conditions of the wafer W to be polished. Alternatively, the control device 50 may control the amount of polishing of the wafer W by changing a pressing force of the polishing pad 21 against the wafer W.

In this manner, the control device 50 can operate the polishing-pad driving source 34 to move the polishing pad 21 along the spiral polishing trajectory, thereby polishing the entire surface of the wafer W uniformly.

In this embodiment, the stage 1 is configured to hold the wafer W without rotating the wafer W. By moving the polishing pad 21 along the spiral polishing trajectory, it is possible to obtain an effect equivalent to that obtained when the wafer W is polished in a rotating state.

Hereinafter, in this specification, an area on the surface to be polished Wa is divided into a peripheral side area PA including the peripheral side portion PP of the wafer W, and a central side area CA including the central portion CP of the wafer W (see FIGS. 3A and 3B, FIGS. 4A and 4B). When the polishing pad 21 is moved along the polishing trajectory while rotating at a constant rotation speed, there is a risk of a difference being generated between the amount of polishing in the peripheral side area PA and the amount of polishing in the central side area CA. For example, there is a risk of over-polishing occurring in the central side area CA.

In order to eliminate such a difference in the amount of polishing, the polishing pad 21 may move at different rotational speeds in the peripheral side area PA and the central side area CA. For example, the rotational speed of the polishing pad 21 in the central side area CA may be slower than the rotational speed of the polishing pad 21 in the peripheral side area PA. In one embodiment, the polishing pad 21 may move in the peripheral side area PA and the central side area CA without rotating.

In one embodiment, the moving speed of the polishing pad 21 may be changed. For example, the moving speed of the polishing pad 21 in the peripheral side area PA may be slower than the moving speed of the polishing pad 21 in the central side area CA.

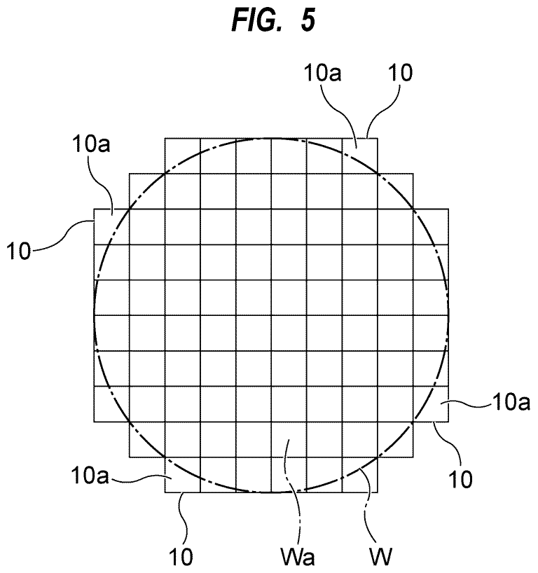

FIG. 5 is a view showing a plurality of pressing actuators arranged in a lattice pattern. In FIG. 5, the stage 1 that houses the pressing actuators 10 is omitted. As shown in FIG. 5, the pressing actuators 10 are arranged in a lattice pattern so as to fill the wafer W, and are spread out along radial and circumferential directions of the wafer W.

Each of the pressing actuators 10 has the same structure. The pressing actuators 10 are configured to be extendable and retractable. The control device 50 is configured to operate the pressing actuators 10 to control the amount of polishing at a specific portion of the wafer W (or other portions excluding the specific portion). An example of the pressing actuators 10 includes a piezoelectric element or an air cylinder.

The pressing actuator 10 has a pressing surface 10a capable of contacting a back surface Wb opposite to the surface to be polished Wa (see FIGS. 2 and 5). The pressing surfaces 10a form the mounting surface of the stage 1. Therefore, when the wafer W is mounted on the mounting surface of the stage 1, the pressing surface 10a of the pressing actuator 10 faces the back surface Wb of the wafer W. The size of the pressing surface 10a is smaller than that of the polishing pad 21.

The pressing actuators 10 are configured to, by their operation, form an uneven shape on the mounting surface of the stage 1 according to the specific portion of the wafer W. When the wafer W is polished, the wafer W is placed on the mounting surface formed by the pressing surfaces 10a.

When the pressing actuator 10 corresponding to the specific portion of the wafer W is operated, the pressing surface 10a presses up the specific portion of the wafer W. The pressed-up specific portion of the wafer W protrudes relative to other portions. In this state, when the polishing pad 21 is pressed against the surface to be polished Wa to polish the wafer W, the specific portion of the wafer W is polished more actively than the other portions. More specifically, the specific portion of the wafer W that protrudes more than the other portions is polished by the polishing pad 21 with a higher pressure than the other portions. Therefore, the amount of polishing of the specific portion is greater than the amount of polishing of the other portions.

When the amount of polishing of the specific portion of the wafer W is to be reduced, the pressing actuator 10 is used to protrude the other portions excluding the specific portion. Alternatively, the pressing actuator 10 corresponding to the specific portion of the wafer W is contracted. When the wafer W is polished in this state, the specific portion of the wafer W is polished by the polishing pad 21 with a pressure lower than that of the other portions.

In one embodiment, as a method for avoiding polishing the specific portion of the wafer W, the pressure of the compressed air supplied to the air bag 22 of the polishing pad 21 may be set to 0, or the polishing pad 21 may be floated above the wafer W.

In this manner, by operating the pressing actuator 10 (and the polishing pad 21) corresponding to the specific portion (and/or other portion) of the wafer W, the amount of polishing at the specific portion (and/or other portion) of the wafer W can be controlled.

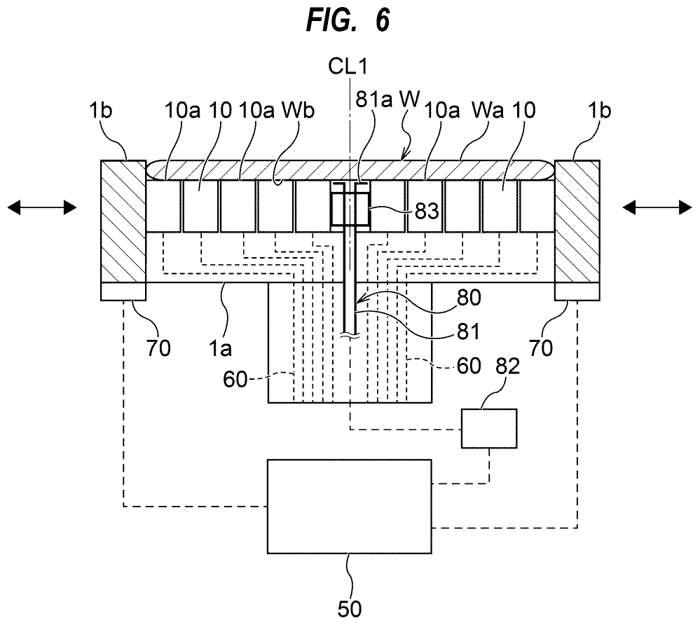

FIG. 6 is a view showing a stage on which the pressing actuators are arranged. As shown in FIG. 6, the stage 1 includes a base 1a on which the pressing actuators 10 are placed, and a plurality of split rings 1b arranged radially outward of the base 1a. The base 1a has a flat plate shape extending parallel to the wafer W held on the stage 1. The pressing actuators 10 are spread out over the base 1a.

The polishing apparatus includes a control line 60 connected to each of the pressing actuators 10, and the pressing actuators 10 are electrically connected to the control device 50 through the control lines 60 extending inside the base 1a (see FIGS. 2 and 6). The number of the control lines 60 corresponds to the number of the pressing actuators 10. The control device 50 is configured to control the operation of each pressing actuator 10 through each control line 60.

In this embodiment, since the stage 1 has a non-rotating structure, it is not necessary to connect the control line 60 to a rotary connector. Therefore, it is possible to simplify the control line 60. Furthermore, since it is not necessary to rotate the control line 60 together with the stage 1, it is possible to prevent disconnection of the control line 60 due to entanglement of the control lines 60.

The split rings 1b are arranged to surround the wafer W arranged on the mounting surface of the stage 1. The split rings 1b have the same structure. In this embodiment, the stage 1 includes four split rings 1b (see FIG. 1), and these split rings 1b have an annular shape surrounding the wafer W.

The split rings 1b are configured to be close to each other and spaced apart from each other. More specifically, the polishing apparatus includes a movement actuator 70 that moves each split ring 1b in a horizontal direction. One example of the movement actuator 70 is an air cylinder or a combination of a ball screw and a servo motor.

The movement actuator 70 is electrically connected to the control device 50. The control device 50 operates the movement actuator 70 to move the split rings 1b close to each other and separate them from each other. When the wafer W is transferred to the stage 1, the control device 50 operates the movement actuator 70 to separate the split rings 1b from each other. In this state, the wafer W is placed on the mounting surface of the stage 1.

Thereafter, the control device 50 operates the movement actuator 70 to move the split rings 1b closer to each other. The split rings 1b that are closer to each other hold the wafer W. The split rings 1b prevent the wafer W from tilting while it is being polished. When the wafer W is held, the surface to be polished Wa of the wafer W is disposed on the same plane as upper surfaces of the split rings 1b.

As shown in FIG. 6, the polishing apparatus includes a suction device 80 that vacuum-sucks the wafer W arranged on the stage 1. The suction device 80 includes a vacuum line 81 attached to the stage 1 and a vacuum source 82 that sucks the wafer W through the vacuum line 81.

The vacuum line 81 is disposed inside the stage 1. More specifically, the vacuum line 81 passes through the base 1a and is disposed in a central portion of the stage 1. The vacuum line 81 extends along the axis line CL1 of the stage 1 and has a suction port 81a formed at its tip. The suction port 81a opens upward and faces the back surface Wb of the wafer W.

The suction port 81a has a flange portion (brim shape) that spreads outward. In one embodiment, the suction port 81a having the flange shape is made of an elastic body such as rubber so as to reliably suck the back surface Wb of the wafer W.

The pressing actuators 10 are arranged around the vacuum line 81. The suction device 80 includes a fixing member 83 to which the vacuum line 81 is attached. The fixing member 83 is configured to fix a relative position of the vacuum line 81 and the pressing actuator 10 arranged around the vacuum line 81. The fixing member 83 to which the vacuum line 81 is attached is attached to the pressing actuators 10 around the vacuum line 81.

The vacuum source 82 is electrically connected to the control device 50, and the control device 50 is configured to control an operation of the vacuum source 82. The vacuum source 82, by its operation, forms a vacuum on the back surface Wb side of the wafer W through the vacuum line 81. In this manner, the suction device 80 vacuum-sucks the wafer W through the suction port 81a of the vacuum line 81, and holds the wafer W by suction.

The polishing apparatus includes a film thickness measuring device 90 (see FIGS. 1 and 2) for detecting a film thickness signal corresponding to the film thickness of the wafer W (more specifically, a film formed on the surface to be polished Wa of the wafer W). An example of the film thickness measuring device 90 includes an optical sensor or an eddy current sensor.

The polishing apparatus includes a film-thickness-measuring-device moving mechanism 100 that moves the film thickness measuring device 90. The film-thickness-measuring-device moving mechanism 100 includes a measurement shaft 101 to which the film thickness measuring device 90 is connected, a measurement arm 102 to which the measurement shaft 101 is connected, a pivot shaft 103 to which the measurement arm 102 is connected, and a film-thickness-measuring-device drive source 104 coupled to the pivot shaft 103.

The film-thickness-measuring-device drive source 104 is configured to move the measurement arm 102 in the X-axis direction and the Y-axis direction via the pivot shaft 103. The film-thickness-measuring-device drive source 104 may have the same structure as the polishing-pad driving source 34 described above, or may have a different structure.

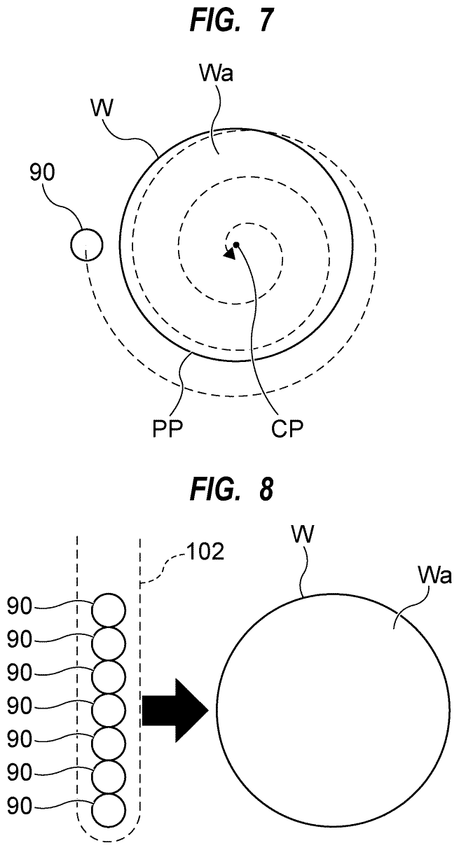

FIG. 7 is a view showing a film thickness measuring device that moves along a spiral measurement trajectory. In FIG. 7, in order to make the drawing easier to see, only the film thickness measuring device 90 and the wafer W are depicted. As shown in FIG. 7, the film thickness measuring device 90 is configured to detect a film thickness signal along the spiral measurement trajectory on the surface to be polished Wa of the wafer W.

The film-thickness-measuring-device driving source 104 is electrically connected to the control device 50. Therefore, the control device 50 is configured to operate the film-thickness-measuring-device driving source 104 to move the film thickness measuring device 90 along the measurement trajectory on the surface to be polished Wa. The film thickness measuring device 90 moves along the measurement trajectory from the peripheral portion PP of the wafer W toward the central portion CP of the wafer W, and acquires a film thickness signal of the entire surface to be polished Wa of the wafer W.

The film thickness measuring device 90 is electrically connected to the control device 50. Therefore, the control device 50 measures the film thickness on the surface to be polished Wa based on the film thickness signal detected by the film thickness measuring device 90, and creates a film thickness profile (film thickness distribution data) of the wafer W.

In this embodiment, the film thickness measuring device 90 is configured to move along the spiral measurement trajectory to detect a film thickness signal of the entire surface to be polished Wa, so that the control device 50 can obtain an accurate film thickness distribution of the surface to be polished Wa.

FIG. 8 is a view showing a plurality of film thickness measuring devices arranged in a line. As shown in FIG. 8, the polishing apparatus may include a plurality of film thickness measuring devices 90. These film thickness measuring devices 90 are arranged in a line in a direction parallel to the surface to be polished Wa, and are attached to the measurement arm 102.

In the embodiment shown in FIG. 8, the film thickness measuring devices 90 are configured to detect film thickness signals of the wafer W along a linear measurement trajectory (see black arrow in FIG. 8) on the surface to be polished Wa. The film-thickness-measuring-device moving mechanism 100 moves the measurement arm 102 linearly in the radial direction of the wafer W, so that the film thickness measuring devices 90 detect the film thickness signals of the wafer W.

The film thickness measuring devices 90 arranged in a straight line have a length equal to or greater than the diameter of the wafer W. Therefore, with a simple configuration in which the measurement arm 102 is moved once, the film thickness measuring devices 90 can detect the film thickness of the wafer W.

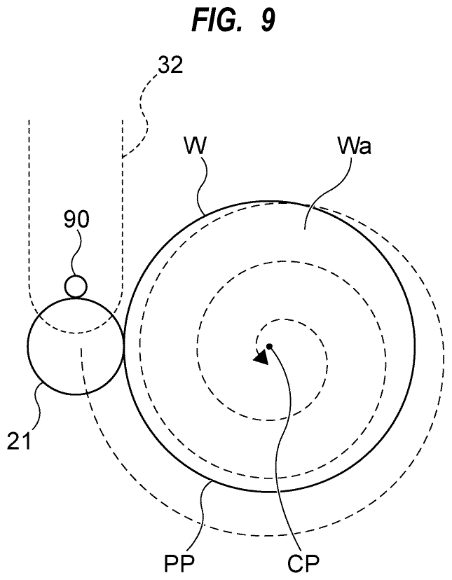

FIG. 9 is a view showing a film thickness measuring device attached to the polishing pad. As shown in FIG. 9, the film thickness measuring device 90 does not necessarily have to be attached to the measurement arm 102 via the measurement shaft 101, but may be attached to the polishing pad arm 32.

In the embodiment shown in FIG. 9, the film thickness measuring device 90 is disposed downstream of the polishing pad 21 in a traveling direction of the polishing pad 21. With this arrangement, the film thickness measuring device 90 can detect the film thickness on the surface to be polished Wa of the wafer W immediately after the polishing pad 21 polishes the surface to be polished Wa of the wafer W. The control device 50 can measure the film thickness on the surface to be polished Wa in real time by acquiring a film thickness signal from the film thickness measuring device 90 while the wafer W is being polished.

The polishing apparatus includes a polishing liquid supplying device 130 that supplies a polishing liquid containing abrasive grains such as silica (SiO₂) onto the surface Wa to be polished (see FIG. 1). The polishing liquid supplying device 130 includes a center supply nozzle 132 and a peripheral supply nozzle 133 for supplying the polishing liquid onto the surface to be polished Wa.

The control device 50 is configured to operate the center supply nozzle 132 and the peripheral supply nozzle 133 to supply the polishing liquid onto the surface to be polished Wa during polishing of the wafer W. The control device 50 moves the polishing pad 21 along the polishing trajectory while supplying the polishing liquid onto the surface to be polished Wa. The polishing pad 21 polishes the surface to be polished Wa with the polishing liquid present on the surface to be polished Wa.

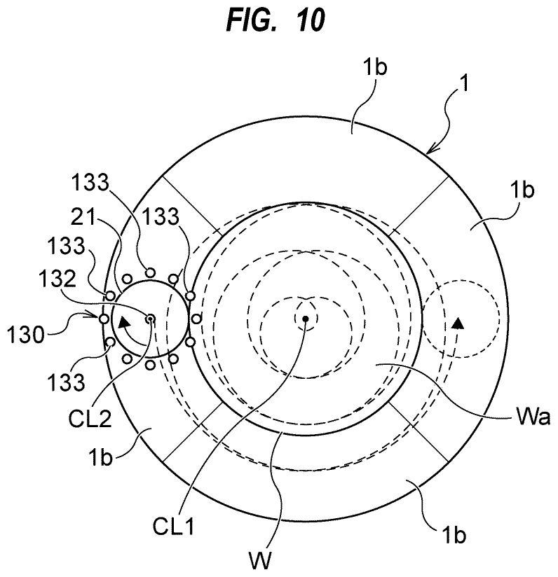

FIG. 10 is a view showing the center supply nozzle and the peripheral supply nozzle. As shown in FIG. 10, the center supply nozzle 132 is configured to supply the polishing liquid from the central portion of the polishing pad 21. The peripheral supply nozzle 133 is configured to supply the polishing liquid around the polishing pad 21.

In the embodiment shown in FIG. 1, the polishing liquid supply device 130 includes one center supply nozzle 132 and two peripheral supply nozzles 133. In the embodiment shown in FIG. 10, the polishing liquid supply device 130 includes one center supply nozzle 132 and twelve peripheral supply nozzles 133.

Thus, there is no particular limitation on the number of center supply nozzles 132 and the number of peripheral supply nozzles 133. In one embodiment, the polishing liquid supply device 130 may include a plurality of center supply nozzles 132 and one peripheral supply nozzle 133. In this embodiment, the plurality of peripheral supply nozzles 133 are disposed at equal intervals in the circumferential direction of the polishing pad 21.

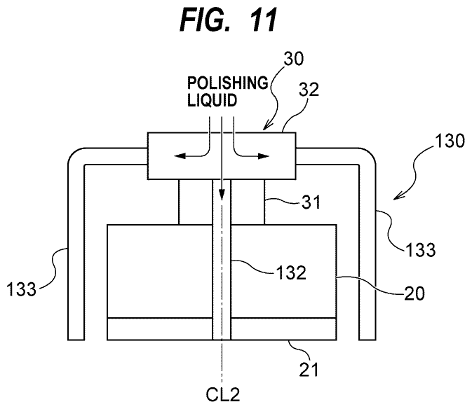

FIG. 11 is a view showing the center supply nozzle and the peripheral supply nozzle connected to the polishing pad arm. As shown in FIG. 11, the center supply nozzle 132 passes through the rotary shaft 31 along the central axis line CL2 and is connected to the polishing pad arm 32. The peripheral supply nozzle 133 is disposed radially outward of the polishing pad 21 and is connected to the polishing pad arm 32.

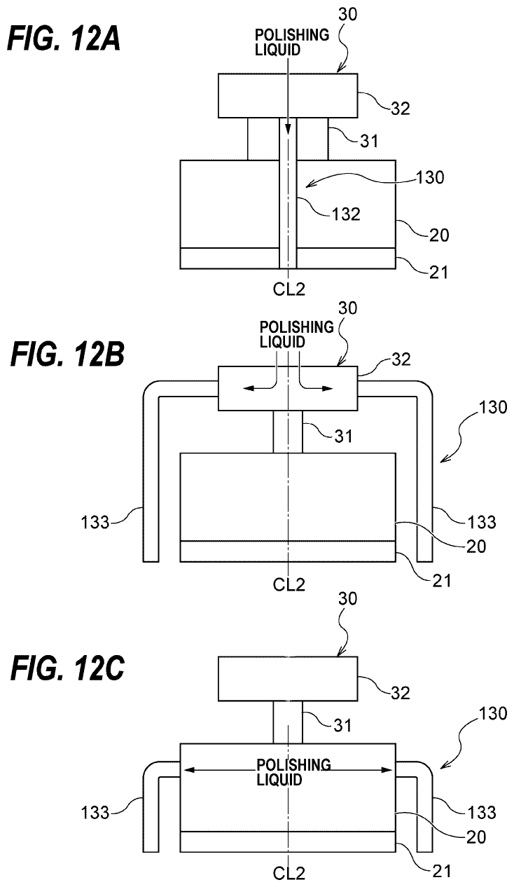

FIG. 12A is a view showing a polishing liquid supply device having only the center supply nozzle, FIG. 12B is a view showing a polishing liquid supply device having only the peripheral supply nozzle, and FIG. 12C is a view showing the peripheral supply nozzle connected to the pad holder.

As shown in FIG. 12A, the polishing liquid supply device 130 may include the center supply nozzle 132 but may not include the peripheral supply nozzle 133. As shown in FIG. 12B, the polishing liquid supply device 130 may include the peripheral supply nozzle 133 but may not include the center supply nozzle 132. Even in this case, the peripheral supply nozzle 133 is configured to supply the polishing liquid to the upstream side of the polishing pad 21 in the traveling direction of the pad holder 20.

In the embodiment shown in FIG. 11, the peripheral supply nozzle 133 connected to the polishing pad arm 32 is configured to be non-rotatable, however, in one embodiment, the peripheral supply nozzle 133 may be configured to be rotatable.

For example, as shown in FIG. 12C, the peripheral supply nozzle 133 may be connected to the pad holder 20. With this configuration, the peripheral supply nozzle 133 can supply the polishing liquid around the polishing pad 21 while rotating together with the pad holder 20. In one embodiment, the peripheral supply nozzle 133 may be connected to the rotary shaft 31. With this configuration, the peripheral supply nozzle 133 also rotates together with the rotary shaft 31.

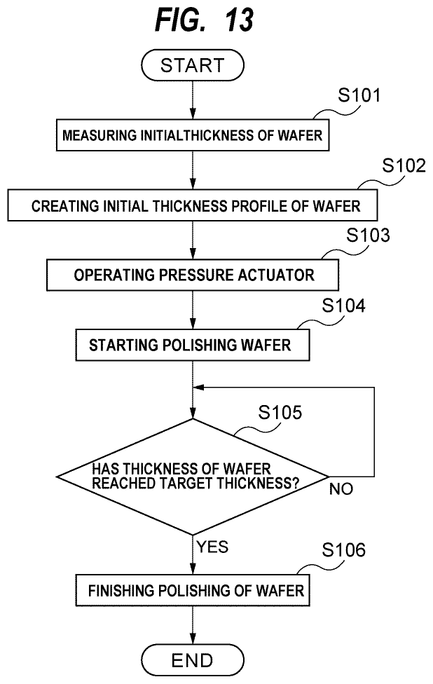

FIG. 13 is a view showing a polishing flow of the wafer by the polishing apparatus. Before starting polishing of the wafer W, the control device 50 measures an initial film thickness over the entire surface to be polished Wa of the wafer W and creates an initial film thickness profile (see steps S101 and S102). The created initial film thickness profile is stored in the storage device 50a.

The initial film thickness profile may be created, for example, from a film thickness signal detected by the film thickness measuring device 90. In this case, the wafer W is held on the stage 1 with its surface to be polished Wa facing upward, and in this state, the film thickness measuring device 90 acquires a film thickness signal of the surface to be polished Wa along the measurement trajectory on the surface to be polished Wa. When holding the wafer W, the control device 50 operates the movement actuator 70 to open the split ring 1b of the stage 1, and when the wafer W is placed on the pressing actuators 10, closes the split ring 1b.

In one embodiment, the control device 50 may create the initial film thickness profile based on a film thickness measurement value obtained by a stand-alone film thickness measurement device (not shown). Even in this case, the initial film thickness profile is stored in the storage device 50a.

Thereafter, the control device 50 compares the initial film thickness profile with a target film thickness profile to create a distribution of a target polishing amount on the surface to be polished Wa. The control device 50 determines a portion (specific portion) to be actively (and/or passively) polished based on the created distribution of the target polishing amount.

In this manner, the control device 50 determines, based on the initial film thickness profile, the pressing force or pressing pressure of the pressing actuator 10 corresponding to the specific portion of the wafer W and/or portions other than the specific portion, against the wafer W. More specifically, the control device 50 determines, based on the created distribution of the target polishing amount, the pressing force or pressing pressure necessary to achieve the target polishing amount within a predetermined polishing time.

The pressing force of the pressing actuator 10 may be adjusted (corrected) depending on the hardness of the polishing pad 21. For example, when a wafer W is polished using a relatively hard polishing pad 21, even if the pressing force of the pressing actuator 10 is small, the pressing force applied to the surface to be polished Wa by the polishing pad 21 changes significantly.

On the other hand, for example, when the wafer W is polished using a relatively soft polishing pad 21, a reaction force that the wafer W receives from the pressing surface 10a of the pressing actuator 10 is absorbed by the polishing pad 21. Therefore, when a magnitude of the pressing force of the pressing actuator 10 is the same as the above pressing force, the pressing force applied by the polishing pad 21 to the surface to be polished Wa does not change significantly.

In this manner, the control device 50 may correct the pressing force of the pressing actuator 10 in accordance with the hardness of the polishing pad 21. Hardness data indicating the hardness of the polishing pad 21 is stored in the storage device 50a.

After determining the pressing force (or pressing pressure) required to achieve the target polishing amount, the control device 50 operates the pressing actuators 10 based on the determined pressing force (see step S103). Thereafter, the control device 50 starts polishing the surface to be polished Wa of the wafer W in a state in which the pressing pressure (or pressing force) of a specific pressing actuator 10 among the pressing actuators 10 is made different from the pressing pressure (or pressing force) of the other pressing actuators 10 (see step S104). The control device 50 may start polishing the surface to be polished Wa of the wafer W without operating the pressing actuator 10 other than the pressing actuator 10 corresponding to the specific portion of the wafer W.

At this time, the control device 50 operates the polishing liquid supply device 130 to supply the polishing liquid onto the surface to be polished Wa from at least one of the center supply nozzle 132 and the peripheral supply nozzle 133.

In this embodiment, the stage 1 has a non-rotating structure. Therefore, when the wafer W is polished, it is possible to prevent the wafer W from shifting in the circumferential direction due to the rotation of the wafer W. As a result, there is no shift in the positional relationship between the specific portion (and/or other portion) of the wafer W and the portion of the wafer W to which the pressing force acts. Therefore, the control device 50 can polish the wafer W with high precision by the polishing pad 21.

When polishing the wafer W, the control device 50 rotates the polishing pad 21 around the central axis line CL2 while supplying the polishing liquid from the polishing liquid supply device 130, and moves the polishing pad 21 along the spiral polishing trajectory on the surface to be polished Wa.

When polishing the wafer W, the control device 50 does not necessarily have to move the polishing pad 21 along the spiral polishing trajectory in accordance with the specific portion (and/or other portions) of the wafer W. For example, when a portion to be polished on the surface to be polished Wa is locally present, the control device 50 may directly move the polishing pad 21 to the local portion and bring the polishing pad 21 into sliding contact with the local portion.

The stage 1 is configured so that, when holding the wafer W, the surface to be polished Wa of the wafer W is disposed on the same plane as the upper surfaces of the split rings 1b. Therefore, the polishing pad 21 can polish the peripheral portion PP of the wafer W without being hindered by the stage 1. When locally polishing the peripheral portion PP of the wafer W, the control device 50 can actively press the polishing pad 21 against the peripheral portion PP by operating the pressing actuator 10 corresponding to the peripheral portion PP to apply the pressing force to the peripheral portion PP.

During polishing of the wafer W, the control device 50 may measure the film thickness of the wafer W by the film thickness measuring device 90. The control device 50 judges whether the film thickness of the wafer W has reached a predetermined target film thickness (i.e., whether the polishing end point has been reached)(see step S105). For example, the control device 50 determines the polishing end point when the difference in film thickness between the thickest and thinnest portions of the wafer W reaches within a predetermined range.

If the film thickness of the wafer W has not reached the target film thickness (see “NO” in step S105), the control device 50 continues polishing the wafer W. On the other hand, if the film thickness of the wafer W has reached the target film thickness (see “YES” in step S105), the control device 50 finishes polishing the wafer W (see step S106).

In one embodiment, the control device 50 may finish (terminate) polishing of the wafer W based on a predetermined polishing time without determining the polishing end point based on the film thickness measurement of the wafer W. For example, the control device 50 may polish the wafer W for a predetermined polishing time, and then measure the film thickness distribution of the wafer W again, and finish polishing of the wafer W when the film thickness distribution of the wafer W reaches a desired film thickness distribution.

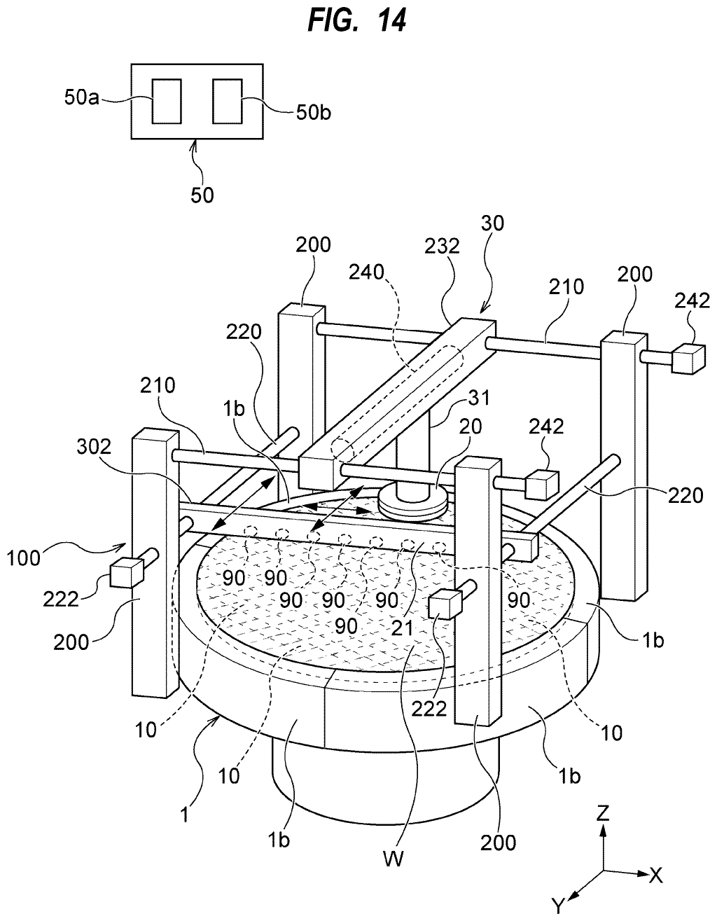

FIG. 14 is a perspective view showing another embodiment of the polishing apparatus. In the embodiment shown in FIG. 14, configurations that are not particularly described are the same as those in the above-described embodiment, so duplicated descriptions will be omitted.

In the embodiment shown in FIG. 14, the polishing apparatus also has configurations corresponding to the polishing liquid supply device 130 and the polishing-pad rotating mechanism 150, but the illustration of these polishing liquid supply device 130 and polishing-pad rotating mechanism 150 is omitted.

As shown in FIG. 14, the polishing-pad moving mechanism 30 includes a polishing pad arm 232 to which a rotary shaft 31 is connected, and a plurality of support rods 210 that movably support the polishing pad arm 232.

The polishing apparatus includes a plurality of support columns 200 arranged around the stage 1. The support columns 200 extend in a Z-axis direction. The Z-axis direction is a direction extending perpendicular to the surface to be polished Wa of the wafer W held on the stage 1, in other words, a direction extending perpendicular to the X-axis direction and the Y-axis direction. The support rods 210 are suspended between adjacent support columns 200 and extend in the X-axis direction.

The polishing-pad moving mechanism 30 includes a moving device 242 that moves the polishing-pad arm 232 in the X-axis direction along the support rod 210, and a linear actuator 240 that moves the polishing pad 21 (and the pad holder 20) in the Y-axis direction together with the rotary shaft 31.

The moving device 242 is, for example, a servo motor coupled to the support rod 210. In this case, the moving device 242 moves the polishing pad 21 (and the rotary shaft 31 and the pad holder 20) together with the polishing-pad arm 232 in the X-axis direction via the support rod 210 through its operation.

The linear actuator 240 is, for example, a combination of a moving body connected to the rotary shaft 31 and a guide rail for moving the moving body in the Y-axis direction. In this case, the linear actuator 240 moves the polishing pad 21 (and the rotary shaft 31 and pad holder 20) in the Y-axis direction together with the moving body by its operation.

The control device 50 is electrically connected to the moving device 242 and the linear actuator 240. Therefore, the control device 50 can freely move the polishing pad 21 (and the pad holder 20) in the X-axis direction and the Y-axis direction by operating the moving device 242 and the linear actuator 240, respectively.

The film-thickness-measuring-device moving mechanism 100 includes a measuring arm 302 to which a plurality of film thickness measuring devices 90 arranged in a straight line are attached, and a support rod 220 that movably supports the measuring arm 302.

The support rods 220 are suspended between adjacent support columns 200 and extend in the Y-axis direction. In the embodiment shown in FIG. 14, the support rods 210 and 220 extend in directions (i.e., the X-axis direction and the Y-axis direction) perpendicular to each other.

The film-thickness-measuring-device moving mechanism 100 includes a moving device 222 that moves the measuring arm 302 in the Y-axis direction along the support rod 220. The moving device 222 is, for example, a servo motor, and may have the same structure as the moving device 242. In this case, the moving device 222 moves the film thickness measuring devices 90 together with the measuring arm 302 in the Y-axis direction simultaneously via the support rod 220 by its operation.

The control device 50 is electrically connected to the moving device 222. Therefore, the control device 50 can freely move the measuring arm 302, to which the film thickness measuring devices 90 are attached, in the Y-axis direction by operating the moving device 222.

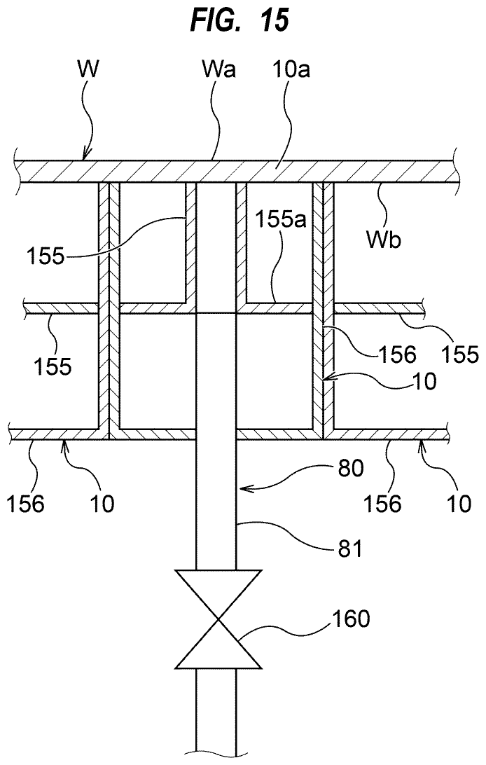

FIG. 15 is a view showing another embodiment of the suction device. In FIG. 15, a single pressing actuator 10 is depicted for ease of viewing the drawing. As shown in FIG. 15, the pressing actuator 10 is an air cylinder having a hollow piston rod 155, a cylinder body 156 that houses the piston rod 155, and a piston 155a that is connected to the piston rod 155 and partitions the inside of the cylinder body 156.

In FIG. 15, an illustration of the supply and exhaust lines connected to upper and lower spaces of the piston 155a is omitted. The control device 50 controls the pressure of the fluid flowing through the supply and exhaust lines to control the pressing pressure of the pressing actuator 10 against the wafer W.

A tip of hollow piston rod 155 serves as a suction port for sucking back surface Wb (i.e., a lower surface) of wafer W. The suction port desirably has a flange portion (not shown) that spreads outward, as in FIG. 6. The flange portion is made of an elastic material such as rubber so as to reliably suck back surface Wb of wafer W.

In the embodiment shown in FIG. 15, the pressing actuator 10 and the vacuum line 81 can be integrally configured. Therefore, it is not necessary to arrange the vacuum line 81 separately from the pressing actuator 10, and the polishing apparatus can achieve space saving of the stage 1.

In FIG. 15, a single vacuum line 81 is arranged for a single pressing actuator 10. The suction device 80 may have a number of vacuum lines 81 corresponding to the number of pressing actuators 10. In one embodiment, the suction device 80 may have a number of vacuum lines 81 less than the number of pressing actuators 10.

In the embodiment shown in FIG. 6, the suction device 80 includes a vacuum line 81 arranged in the central portion of the stage 1, but in one embodiment, the suction device 80 may include a plurality of vacuum lines 81 arranged evenly over the entire mounting surface of the stage 1. Such an arrangement prevents the suction pressure from acting locally on the wafer W, and allows the suction pressure to act evenly over the entire surface of the wafer W. In one embodiment, the embodiment shown in FIG. 6 and the embodiment shown in FIG. 15 may be combined.

In the embodiment shown in FIG. 15, the suction device 80 includes a control valve 160 instead of the vacuum source 82 (see FIG. 6). In this manner, the suction device 80 does not necessarily include the vacuum source 82. For example, the vacuum line 81 may be connected to a utility line (not shown) for forming a vacuum that is installed in a factory.

In this case, the control device 50 operates the control valve 160 attached to the vacuum line 81 to form a vacuum on the back surface Wb side of the wafer W. Similarly, in the embodiment shown in FIG. 6, the suction device 80 may include the control valve 160 instead of the vacuum source 82.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A polishing apparatus comprising:
a stage configured to hold a substrate with a surface to be polished facing upward, and having a non-rotating structure;
a plurality of pressing actuators arranged inside the stage, and configured to independently press a specific portion of the substrate;
a pad holder configured to hold a polishing pad and press the polishing pad against the surface to be polished; and
a polishing-pad rotating mechanism configured to rotate the polishing pad about its own center.

2. The polishing apparatus according to claim 1, wherein the polishing apparatus comprises a polishing-pad moving mechanism configured to move the polishing pad.

3. The polishing apparatus according to claim 2, wherein the polishing-pad moving mechanism is configured to move the polishing pad along a spiral polishing trajectory on the surface to be polished.

4. The polishing apparatus according to claim 3,
wherein the polishing trajectory has:
a first trajectory extending from a peripheral portion of the substrate toward a central portion of the substrate; and
a second trajectory extending from the central portion of the substrate toward the peripheral portion of the substrate, and not overlapping with the first trajectory.

5. The polishing apparatus according to claim 1, wherein the polishing apparatus includes a film thickness measuring device configured to detect a film thickness signal corresponding to a film thickness of the substrate.

6. The polishing apparatus according to claim 5,
wherein the polishing apparatus comprises a plurality of film thickness measuring devices, including the film thickness measuring device, arranged in a straight line, and
wherein the film thickness measuring devices are configured to detect a film thickness signal corresponding to the film thickness of the substrate along a linear measurement trajectory on the surface to be polished.

7. The polishing apparatus according to claim 1, wherein the polishing apparatus comprises a polishing liquid supply device having a center supply nozzle configured to supply a polishing liquid from a center portion of the polishing pad.

8. The polishing apparatus according to claim 1,
wherein the polishing apparatus comprises a polishing liquid supply device having a peripheral supply nozzle arranged around the polishing pad, and
wherein the peripheral supply nozzle is configured to supply a polishing liquid to an upstream side of the polishing pad in a traveling direction of the polishing pad.

9. The polishing apparatus according to claim 1,
wherein the polishing apparatus comprises a suction device configured to vacuum-suck the substrate arranged on the stage, and
wherein the suction device comprises a vacuum line disposed inside the stage.

10. The polishing apparatus according to claim 9,
wherein at least one of the pressing actuators is an air cylinder having a hollow piston rod, and
wherein the vacuum line is connected to the piston rod.

11. A polishing method comprising:
holding a substrate with a surface to be polished of the substrate facing upward by a stage configured to house a plurality of pressing actuators; and
polishing the substrate in a non-rotating state by pressing a polishing pad held by a pad holder against the surface to be polished while rotating the polishing pad around itself in a state in which a pressing pressure of a specific pressing actuator among a plurality of pressing actuators is made different from a pressing pressure of the other pressing actuators.

12. The polishing method according to claim 11, comprising: moving the polishing pad along a spiral polishing trajectory on the surface to be polished when polishing the substrate.

13. The polishing method according to claim 11, comprising:
measuring a film thickness distribution of the substrate before polishing the substrate; and
determining the pressing pressure by the pressing actuators based on the film thickness distribution.

14. The polishing method according to claim 11, comprising: supplying a polishing liquid from a center supply nozzle disposed at a center portion of the polishing pad when polishing the substrate.

15. The polishing method according to claim 11, comprising: supplying a polishing liquid from a peripheral supply nozzle disposed around the polishing pad to an upstream side of the polishing pad in a traveling direction of the polishing pad when polishing the substrate.
